(19) United States
(12) Patent Application Publication
(10) Pub. No.: US 2025/0120046 A1
(43) Pub. Date: Apr. 10, 2025

(54) VEHICLE TEMPERATURE CONTROL SYSTEM AND VEHICLE

(71) Applicant: HONDA MOTOR CO., LTD., Tokyo (JP)

(72) Inventor: Kenta SAKANE, Tokyo (JP)

(73) Assignee: HONDA MOTOR CO., LTD., Tokyo (JP)

(21) Appl. No.: 18/911,293

(22) Filed: Oct. 10, 2024

(30) Foreign Application Priority Data
Oct. 10, 2023 (JP) 2023-175048

(51) Int. Cl. H05K 7/20; B60K 11/04

(52) U.S. Cl. CPC H05K 7/20281; H05K 7/20872; B60K 11/04

(57) ABSTRACT

A vehicle temperature control system is configured to cause a flow regulating valve to close, when temperature of a first temperature control medium detected by a first temperature control medium temperature detector is lower than a predetermined temperature, and cause the flow regulating valve to open, when the temperature of the first temperature control medium detected by the first temperature control medium temperature detector becomes equal to or higher than the predetermined temperature while the flow regulating valve is closed.

### CROSS-REFERENCE TO RELATED APPLICATIONS

This application is based on and claims priority under 35 USC 119 from Japanese Patent Application No. 2023-175048 filed on Oct. 10, 2023, the contents of which are incorporated herein by reference.

### TECHNICAL FIELD

The present disclosure relates to a vehicle temperature control system equipped in an electric vehicle or the like, and relates to a vehicle.

### BACKGROUND

In recent years, efforts to realize a low-carbon society or a decarbonized society become active, and research and development about electrification techniques for vehicles are conducted to reduce CO₂ emission and improve energy efficiency in vehicles.

In general, an electric vehicle includes a rotary electric machine and a power conversion device that controls electric power supplied to the rotary electric machine. When the electric vehicle is driven, the rotary electric machine and the power conversion device generate heat, and therefore, the electric vehicle is usually equipped with a vehicle temperature control system for controlling temperatures of the rotary electric machine and the power conversion device.

In the electrification techniques for vehicles, there is a demand for more efficient cooling of the rotary electric machine and the power conversion device while further improving fuel efficiency of a vehicle.

One method for improving the fuel efficiency of a vehicle is to prevent an increase in friction loss in the rotary electric machine and a gear box. For example, Japanese Patent Publication No. 7314222 (hereinafter, referred to as Patent Literature 1) describes a vehicle temperature control system configured to control a flow regulating valve based on a temperature of a first temperature control medium for controlling temperatures of a rotary electric machine and a gear box, and a temperature of a second temperature control medium for controlling a temperature of a power conversion device, thereby preventing an increase in friction loss in the rotary electric machine and the gear box. However, in the vehicle temperature control system of Patent Literature 1, the valve device may be open even when the temperature of the first temperature control medium is equal to or lower than a predetermined temperature, so there was room for further improvement to prevent an increase in friction loss in the gear box. Especially, when the temperature of the first temperature control medium is equal to or lower than a predetermined temperature, cooling of the rotary electric machine is unnecessary, and therefore it is preferable to increase the temperature of the first temperature control medium as early as possible to reduce a viscosity of the first temperature control medium.

The present disclosure provides a vehicle temperature control system and a vehicle capable of cooling a rotary electric machine when cooling of the rotary electric machine is necessary, while improving fuel efficiency of the vehicle when cooling of the rotary electric machine is unnecessary.

### SUMMARY

A first aspect of the present disclosure relates to a vehicle temperature control system equipped in a vehicle including a rotary electric machine, a transmission device, and a power conversion device configured to control electric power supplied to the rotary electric machine. The vehicle temperature control system includes: a first temperature control circuit in which a first pump is provided and a first temperature control medium circulates to control temperatures of the rotary electric machine and the transmission device; a second temperature control circuit in which a second pump is provided and a second temperature control medium circulates to control a temperature of the power conversion device; a heat exchanger that exchanges heat between the first temperature control medium and the second temperature control medium; a flow regulating valve configured to regulate a flow rate of the second temperature control medium flowing through the heat exchanger; and a control device configured to control the flow regulating valve. The second temperature control circuit includes a pumping flow path provided with the second pump and having one end provided with a branch portion and the other end provided with a merging portion, a first branching flow path provided with the power conversion device and having one end connected to the branch portion and the other end connected to the merging portion, and a second branching flow path provided with the heat exchanger and the flow regulating valve, having one end connected to the branch portion and the other end connected to the merging portion, and formed in parallel with the first branching flow path. The pumping flow path is provided with a radiator configured to exchange heat between the second temperature control medium and outside air. The control device includes a first temperature control medium temperature detector configured to detect a temperature of the first temperature control medium, and a valve opening and closing controller configured to control opening and closing of the flow regulating valve. The valve opening and closing controller is configured to cause the flow regulating valve to close, when the temperature of the first temperature control medium detected by the first temperature control medium temperature detector is lower than a predetermined temperature, and cause the flow regulating valve to open, when the temperature of the first temperature control medium detected by the first temperature control medium temperature detector becomes equal to or higher than the predetermined temperature while the flow regulating valve is closed.

A second aspect of the present disclosure relates to a vehicle. The vehicle includes: a rotary electric machine; a transmission device; a power conversion device configured to control electric power supplied to the rotary electric machine; and a vehicle temperature control system. The vehicle temperature control system includes a first temperature control circuit in which a first pump is provided and a first temperature control medium circulates to control temperatures of the rotary electric machine and the transmission device, a second temperature control circuit in which a second pump is provided and a second temperature control medium circulates to control a temperature of the power conversion device, a heat exchanger that exchanges heat between the first temperature control medium and the second temperature control medium, a flow regulating valve configured to regulate a flow rate of the second temperature control medium flowing through the heat exchanger, and a control device configured to control the flow regulating valve. The second temperature control circuit includes a pumping flow path provided with the second pump and having one end provided with a branch portion and the other end provided with a merging portion, a first branching flow path provided with the power conversion device and having one end connected to the branch portion and the other end connected to the merging portion, and a second branching flow path provided with the heat exchanger and the flow regulating valve, having one end connected to the branch portion and the other end connected to the merging portion, and formed in parallel with the first branching flow path. The pumping flow path is provided with a radiator configured to exchange heat between the second temperature control medium and outside air. The control device includes a first temperature control medium temperature detector configured to detect a temperature of the first temperature control medium, and a valve opening and closing controller configured to control opening and closing of the flow regulating valve, and the valve opening and closing controller is configured to cause the flow regulating valve to close, when the temperature of the first temperature control medium detected by the first temperature control medium temperature detector is lower than a predetermined temperature, and cause the flow regulating valve to open, when the temperature of the first temperature control medium detected by the first temperature control medium temperature detector becomes equal to or higher than the predetermined temperature while the flow regulating valve is closed.

### BRIEF DESCRIPTION OF DRAWINGS

Exemplary embodiments of the present disclosure will be described in detail based on the following figures, wherein

FIG. 1 is a block diagram of a vehicle temperature control system according to an embodiment of the present disclosure;

FIG. 2A is a diagram showing a configuration of a valve device in the vehicle temperature control system of FIG. 1;

FIG. 2B is a diagram showing a configuration of a valve device in the vehicle temperature control system of FIG. 1;

FIG. 3 is a block diagram of a control device in the vehicle temperature control system of FIG. 1; and

FIG. 4 is a flowchart showing a control flow of the valve device in a valve opening and closing control unit in the control device of FIG. 3.

### DESCRIPTION OF EMBODIMENTS

Hereinafter, an embodiment of a vehicle equipped with a vehicle temperature control system of the present disclosure will be described with reference to the accompanying drawings. Note that the drawings are viewed in directions of reference numerals.

### Overall Configuration of Vehicle Temperature Control System

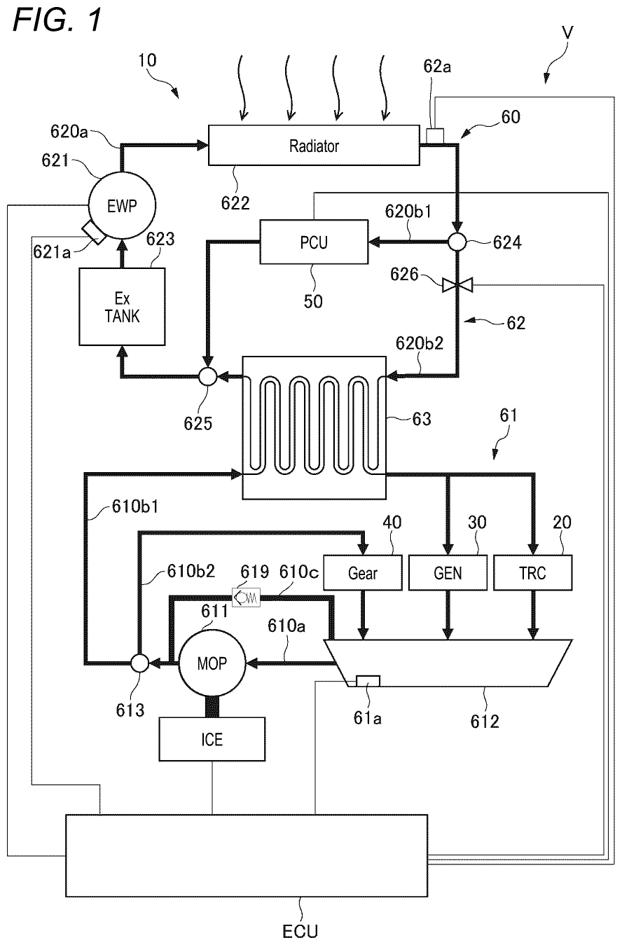

As shown in FIG. 1, the vehicle temperature control system 10 of the present embodiment is equipped in a vehicle V including an internal combustion engine ICE, a control device ECU, an electric motor 20, an electric generator 30, a transmission device 40, and a power conversion device 50.

The vehicle temperature control system 10 includes the internal combustion engine ICE, the control device ECU, the electric motor 20, the electric generator 30, the transmission device 40, the power conversion device 50, and a temperature control circuit 60.

The electric motor 20 is a rotary electric machine that outputs power for driving the vehicle V using electric power stored in a power storage device (not shown) equipped in the vehicle V, or electric power generated by the electric generator 30. During braking of the vehicle V, the electric motor 20 may generate electric power using kinetic energy of driving wheels of the vehicle V and charge the above power storage device.

The electric generator 30 is a rotary electric machine that generates electric power using power of the internal combustion engine ICE. The electric generator 30 charges the above power storage device or supplies electric power to the electric motor 20.

The transmission device 40 is a device that reduces a speed of the power output from the electric motor 20 and transmits the power to the driving wheels. The transmission device 40 is, for example, a gear-type power transmission device.

The power conversion device 50 includes a power drive unit (PDU) (not shown) that converts the electric power output from the above power storage device from DC to AC and controls input and output electric power of the electric motor 20 and the electric generator 30, and a voltage control unit (VCU) (not shown) that boosts the electric power output from the above power storage device as necessary. When the electric motor 20 generates electric power during braking of the vehicle V, the VCU may buck a voltage of the electric power generated by the electric motor 20.

The temperature control circuit 60 includes a first temperature control circuit 61 in which a non-conductive first temperature control medium TCM1 circulates and configured to control temperatures of the electric motor 20, the electric generator 30, and the transmission device 40, a second temperature control circuit 62 in which a conductive second temperature control medium TCM2 circulates and configured to control a temperature of the power conversion device 50, and a heat exchanger 63 configured to exchange heat between the first temperature control medium TCM1 and the second temperature control medium TCM2. The non-conductive first temperature control medium TCM1 is, for example, an oil called an automatic transmission fluid (ATF) capable of lubricating and controlling the temperatures of the electric motor 20, the electric generator 30, and the transmission device 40. The conductive second temperature control medium TCM2 is, for example, a cooling water called a long life coolant (LLC).

### Configuration of First Temperature Control Circuit

The first temperature control circuit 61 is provided with a first pump 611 and a storage portion 612. The first pump 611 is a mechanical pump driven by the power of the internal combustion engine ICE and a rotating force of an axle (not shown) of the vehicle V. The storage portion 612 stores the first temperature control medium TCM1 circulating in the first temperature control circuit 61. The storage portion 612 is, for example, an oil pan provided at a bottom of a housing (not shown) that accommodates the electric motor 20, the electric generator 30, and the transmission device 40.

The first temperature control circuit 61 is provided with a first pump 611 and includes a pumping flow path 610a whose upstream end is connected to the storage portion 612. A branch portion 613 is provided at a downstream end of the pumping flow path 610a.

The first temperature control circuit 61 is provided with the heat exchanger 63, the electric motor 20, and the electric generator 30, and includes a first branching flow path 610b1 whose upstream end is connected to the branch portion 613 and whose downstream end is connected to the storage portion 612. In the first branching flow path 610b1, the heat exchanger 63 is disposed upstream of the electric motor 20 and the electric generator 30, and the electric motor 20 and the electric generator 30 are arranged in parallel with each other. The first temperature control circuit 61 is provided with the transmission device 40 and includes a second branching flow path 610b2 whose upstream end is connected to the branch portion 613 and whose downstream end is connected to the storage portion 612.

Therefore, in the first temperature control circuit 61, a flow path in which the first temperature control medium TCM1 pumped by the first pump 611 in the pumping flow path 610a passes from the branch portion 613 through the first branching flow path 610b1, is cooled by heat exchange with the second temperature control medium TCM2 in the heat exchanger 63, is supplied to the electric motor 20 and the electric generator 30 to lubricate and control the temperatures of the electric motor 20 and the electric generator 30, and is then stored in the storage portion 612, and a flow path in which the first temperature control medium TCM1 pumped by the first pump 611 in the pumping flow path 610a passes from the branch portion 613 through the second branching flow path 610b2, is supplied to the transmission device 40 to lubricate and control the temperature of the transmission device 40, and is then stored in the storage portion 612, are formed in parallel, and the first temperature control medium TCM1 stored in the storage portion 612 flows through the pumping flow path 610a and is supplied to the first pump 611 so that the first temperature control medium TCM1 circulates in the first temperature control circuit 61.

In the present embodiment, the first branching flow path 610b1 and the second branching flow path 610b2 are formed so that a flow rate of the first temperature control medium TCM1 flowing through the first branching flow path 610b1 is greater than a flow rate of the first temperature control medium TCM1 flowing through the second branching flow path 610b2.

The first temperature control circuit 61 is provided with a first temperature sensor 61a that detects a temperature of the first temperature control medium TCM1 circulating in the first temperature control circuit 61. In the present embodiment, the first temperature sensor 61a is provided in the storage portion 612, which is an oil pan, and detects the temperature of the first temperature control medium TCM1 stored in the storage portion 612. The first temperature sensor 61a outputs, to the control device ECU, a detection value of the temperature of the first temperature control medium TCM1 stored in the storage portion 612.

The first temperature control circuit 61 further includes a pressure regulating circuit 610c whose upstream end is connected to the storage portion 612 and whose downstream end is connected to the pumping flow path 610a downstream of the first pump 611. The pressure regulating circuit 610c is provided with a pressure regulating valve 619. The pressure regulating valve 619 may be a check valve or an electromagnetic valve such as a solenoid valve. When a liquid pressure of the first temperature control medium TCM1 pumped from the first pump 611 is equal to or higher than a predetermined upper limit pressure, the pressure regulating valve 619 is in an open state, and a part of the first temperature control medium TCM1 pumped from the first pump 611 is returned to the storage portion 612. As a result, the liquid pressure of the first temperature control medium TCM1 flowing through the first branching flow path 610b1 and the second branching flow path 610b2 is kept equal to or lower than the predetermined upper limit pressure.

In the first temperature control circuit 61, the temperature of the first temperature control medium TCM1 stored in the storage portion 612 after cooling the electric motor 20, the electric generator 30, and the transmission device 40 is approximately 100 [° C.]. Therefore, the first temperature control medium TCM1 at approximately 100 [° C.] is supplied to the heat exchanger 63.

### Configuration of Second Temperature Control Circuit

The second temperature control circuit 62 is provided with a second pump 621, a radiator 622, a storage tank 623, and the power conversion device 50. The second pump 621 is, for example, an electric pump driven by the electric power stored in the above-mentioned power storage device. A rotation speed sensor 621a that detects a rotation speed of the second pump 621 is attached to the second pump 621. The rotation speed sensor 621a outputs a detection value of the rotation speed of the second pump 621 to the control device ECU. The radiator 622 is disposed in a front portion of the vehicle V, and is a heat dissipation device that exchanges heat between the second temperature control medium TCM2 and outside air by a travel wind when the vehicle V travels, thereby cooling the second temperature control medium TCM2. The storage tank 623 is a tank that temporarily stores the second temperature control medium TCM2 circulating in the second temperature control circuit 62. Even when cavitation occurs in the second temperature control medium TCM2 circulating in the second temperature control circuit 62, by temporarily storing the second temperature control medium TCM2 circulating in the second temperature control circuit 62 in the storage tank 623, the cavitation occurring in the second temperature control medium TCM2 will disappear.

The second temperature control circuit 62 includes a pumping flow path 620a provided with the storage tank 623, the second pump 621, and the radiator 622 in this order from an upstream side. A merging portion 625 is provided at an upstream end of the pumping flow path 620a, and a branch portion 624 is provided at a downstream end of the pumping flow path 620a. Therefore, the second temperature control medium TCM2 that flows from the merging portion 625 into the pumping flow path 620a is temporarily stored in the storage tank 623, and then pumped by the second pump 621 and supplied to the radiator 622, cooled by heat exchange with the outside air, and flows to the branch portion 624.

The second temperature control circuit 62 further includes a first branching flow path 620b1 in which the power conversion device 50 is provided and whose upstream end is connected to the branch portion 624 and passes through the power conversion device 50, and whose downstream end is connected to the merging portion 625, and a second branching flow path 620b2 in which the heat exchanger 63 is provided and whose upstream end is connected to the branch portion 624 and passes through the heat exchanger 63, and whose downstream end is connected to the merging portion 625. In the present embodiment, a valve device 626 is provided upstream of the heat exchanger 63 in the second branching flow path 620b2. In the present embodiment, the valve device 626 is a solenoid valve that switches the second branching flow path 620b2 between a fully open state and a fully closed state. The valve device 626 is controlled by the control device ECU. A detailed configuration of the valve device 626 will be described later.

Therefore, the second temperature control medium TCM2 pumped by the second pump 621 in the pumping flow path 620a and cooled by the radiator 622 branches at the branch portion 624 into the first branching flow path 620b1 and the second branching flow path 620b2. The second temperature control medium TCM2 flowing through the first branching flow path 620b1 cools the power conversion device 50 and merges with the second branching flow path 620b2 and the pumping flow path 620a at the merging portion 625. The second temperature control medium TCM2 flowing through the second branching flow path 620b2 cools the first temperature control medium TCM1 by heat exchange with the first temperature control medium TCM1 in the heat exchanger 63, and merges with the first branching flow path 620b1 and the pumping flow path 620a at the merging portion 625. The second temperature control medium TCM2 flowing through the first branching flow path 620b1 and the second temperature control medium TCM2 flowing through the second branching flow path 620b2 merge at the merging portion 625, flow through the pumping flow path 620a, and are temporarily stored in the storage tank 623. Then, the second temperature control medium TCM2 stored in the storage tank 623 is supplied again to the second pump 621 through the pumping flow path 620a, and the second temperature control medium TCM2 circulates in the second temperature control circuit 62.

In the present embodiment, the first branching flow path 620b1 and the second branching flow path 620b2 are formed so that the flow rate of the second temperature control medium TCM2 flowing through the first branching flow path 620b1 is greater than the flow rate of the second temperature control medium TCM2 flowing through the second branching flow path 620b2.

The second temperature control circuit 62 is provided with a second temperature sensor 62a that detects a temperature of the second temperature control medium TCM2 circulating in the second temperature control circuit 62. In the present embodiment, the second temperature sensor 62a is provided between the radiator 622 and the branch portion 624 in the pumping flow path 620a, and detects the temperature of the second temperature control medium TCM2 discharged from the radiator 622. The second temperature sensor 62a outputs, to the control device ECU, a detection value of the temperature of the second temperature control medium TCM2 discharged from the radiator 622.

In the second temperature control circuit 62, the temperature of the second temperature control medium TCM2 cooled by the radiator 622 is approximately 40 [° C.]. Since the second temperature control medium TCM2 supplied to the heat exchanger 63 does not pass through the power conversion device 50 whose temperature is to be controlled, the second temperature control medium TCM2 at approximately 40 [° C.] is supplied to the heat exchanger 63.

### Configuration of Heat Exchanger

The heat exchanger 63 performs heat exchange between the first temperature control medium TCM1 at approximately 100 [° C.] and the second temperature control medium TCM2 at approximately 40 [° C.] supplied to the heat exchanger 63. Then, from the heat exchanger 63, the first temperature control medium TCM1 at approximately 80 [° C.] is discharged to a downstream side of the first branching flow path 610b1 of the first temperature control circuit 61, and the second temperature control medium TCM2 at approximately 70 [° C.] is discharged to a downstream side of the second branching flow path 620b2 of the second temperature control circuit 62.

In this way, since the first temperature control medium TCM1 is cooled by the heat exchanger 63, the first temperature control medium TCM1 can be cooled in the temperature control circuit 60 without any radiator for cooling the first temperature control medium TCM1. Therefore, the temperature control circuit 60 can cool the first temperature control medium TCM1 flowing through the first temperature control circuit 61 and the second temperature control medium TCM2 flowing through the second temperature control circuit 62 with one radiator 622, so that the temperature control circuit 60 can be miniaturized.

### Configuration of Valve Device

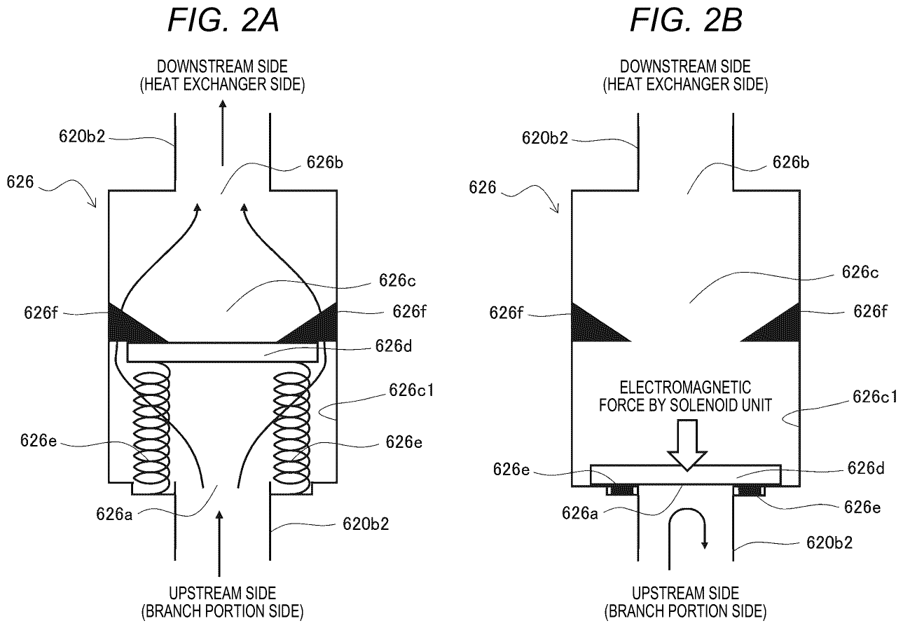

Next, a configuration of the valve device 626 will be described with reference to FIGS. 2A and 2B.

As shown in FIGS. 2A and 2B, the valve device 626 includes an inlet 626a through which the second temperature control medium TCM2 flows in, an outlet 626b through which the second temperature control medium TCM2 is discharged, an in-valve flow path 626c extending from the inlet 626a to the outlet 626b, a valve body member 626d provided in the in-valve flow path 626c for opening and closing the in-valve flow path 626c, a biasing member 626e for biasing the valve body member 626d, and a solenoid unit (not shown) capable of generating an electromagnetic force.

In the present embodiment, the in-valve flow path 626c extends in a substantially straight line, and the valve body member 626d is provided in the vicinity of the inlet 626a. The valve body member 626d is provided in a manner in which the valve body member 626d slides along an inner wall surface 626c1 of the in-valve flow path 626c. The valve body member 626d is shaped so as to be able to block the inlet 626a. In the present embodiment, the valve body member 626d has a disk shape. The valve body member 626d is attracted by the electromagnetic force generated by the solenoid unit (not shown). The biasing member 626e is, for example, an elastic member such as a coil spring. One end of the biasing member 626e is connected to an end on the inlet 626a side of the in-valve flow path 626c, and the other end of the biasing member 626e is connected to the valve body member 626d. The biasing member 626e biases the valve body member 626d in a direction away from the inlet 626a.

A locking portion 626f is formed in the in-valve flow path 626c, closer to the outlet 626b than the valve body member 626d. The locking portion 626f is, for example, a protrusion that protrudes toward a flow path center of the in-valve flow path 626c. The locking portion 626f is capable of locking the valve body member 626d which is slidable along the inner wall surface 626c1 of the in-valve flow path 626c.

As shown in FIG. 2A, the valve device 626 is in a fully open state when the solenoid unit (not shown) is in an off state and generates no electromagnetic force. In this case, the valve body member 626d is biased in a direction away from the inlet 626a by the biasing force of the biasing member 626e, and is in a state of being locked by the locking portion 626f.

As shown in FIG. 2B, the valve device 626 is in a fully closed state when the solenoid unit (not shown) is in an on state and generates an electromagnetic force. In this case, the valve body member 626d is attracted toward the inlet 626a by the electromagnetic force generated by the solenoid unit (not shown), and is moved toward the inlet 626a against the biasing force of the biasing member 626e, thereby blocking the inlet 626a.

Then, when the solenoid unit (not shown) is set to an off state again to transition the valve device 626 to a fully open state, the valve body member 626d is moved toward a direction away from the inlet 626a by a combined force of a fluid pressure of the second temperature control medium TCM2 at the inlet 626a and the biasing force of the biasing member 626e. In this case, if the fluid pressure of the second temperature control medium TCM2 flowing from the outlet 626b side toward the valve body member 626d is not greater than the combined force of the fluid pressure of the second temperature control medium TCM2 at the inlet 626a and the biasing force of the biasing member 626e, the valve device 626 can be transitioned to a fully open state. When the valve device 626 is in a fully closed state, a pressure on an upstream side, that is, on the inlet 626a side, of the valve device 626 is high and a pressure on a downstream side, that is, on the outlet 626b side, of the valve device 626 is low, so that the fluid pressure of the second temperature control medium TCM2 flowing from the outlet 626b side toward the valve body member 626d is unlikely to become greater than the combined force of the fluid pressure of the second temperature control medium TCM2 at the inlet 626a and the biasing force of the biasing member 626e.

In this way, the valve device 626 is configured so that, when in a fully closed state, the valve body member 626d moves toward the inlet 626a to block the inlet 626a, thereby preventing the valve device 626 from becoming stuck in the fully closed state. Furthermore, since the biasing force of the biasing member 626e required when transitioning the valve device 626 from the fully closed state to the fully open state can be reduced, a cost of the biasing member 626e can be reduced, and a cost of the valve device 626 can be reduced.

### Configuration of Control Device

The control device ECU controls the internal combustion engine ICE, the power conversion device 50, the second pump 621, and the valve device 626. The control device ECU may detect a failure of the heat exchanger 63 based on the detection value of the rotation speed of the second pump 621 output from the rotation speed sensor 621a. For example, the control device ECU may detect a failure of the heat exchanger 63 by determining that the heat exchanger 63 fails when a fluctuation range of the detection value of the rotation speed of the second pump 621 output from the rotation speed sensor 621a relative to a target rotation speed is equal to or greater than a predetermined value.

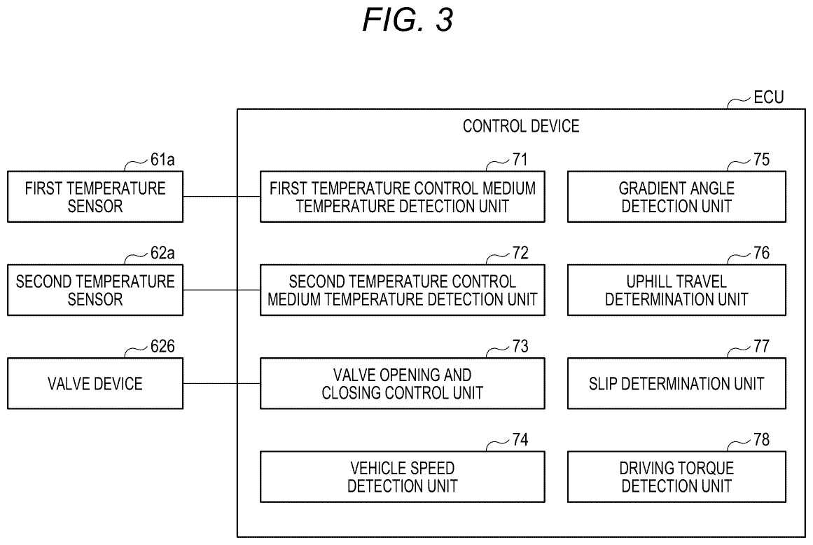

As shown in FIG. 3, the control device ECU includes a first temperature control medium temperature detection unit 71 that detects the temperature of the first temperature control medium TCM1 based on a signal from the first temperature sensor 61a, a second temperature control medium temperature detection unit 72 that detects the temperature of the second temperature control medium TCM2 based on a signal from the second temperature sensor 62a, a valve opening and closing control unit 73 that controls opening and closing of the valve device 626, a vehicle speed detection unit 74 that detects a vehicle speed of the vehicle V, a gradient angle detection unit 75 that detects a gradient angle of a road surface on which the vehicle V travels, an uphill travel determination unit 76 that determines whether the vehicle V is in uphill travel based on the detection values of the vehicle speed detection unit 74 and the gradient angle detection unit 75, a slip determination unit 77 that determines whether at least one wheel of the vehicle V is spinning, and a driving torque detection unit 78 that detects a driving torque of the vehicle V.

### Control Flow for Valve Device in Valve Opening and Closing Control Unit in Control Device

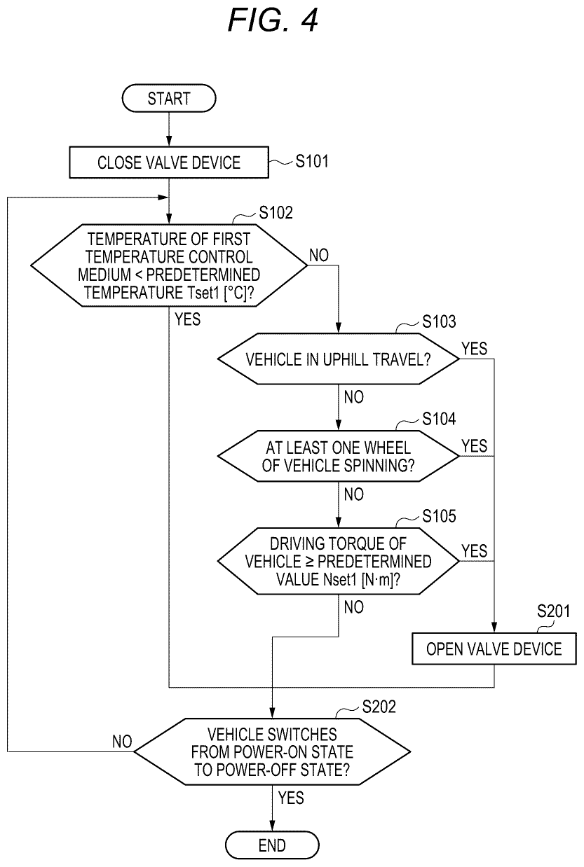

Next, a control flow for the valve device 626 in the valve opening and closing control unit 73 in the control device ECU will be described with reference to FIG. 4.

The control flow for the valve device 626 in the valve opening and closing control unit 73 starts when the vehicle V switches from a power-off state to a power-on state. The power-on state of the vehicle V refers to a state in which a power system of the vehicle V is turned on, at least one of the internal combustion engine ICE and the electric motor 20, which are drive sources of the vehicle V, is started, and electric power required to drive the vehicle V is supplied to auxiliary equipment required for the traveling of the vehicle V, and also refers to a state in which the vehicle V is in travel or a state in which the vehicle V is able to travel immediately. An operation to turn on the power system refers to, for example, an operation of turning on a power switch (not shown) provided in the vehicle V by an operator of the vehicle V. The power system may be turned on by the operator of the vehicle V turning on an ignition switch for starting the internal combustion engine ICE.

First, when the vehicle V switches from the power-off state to the power-on state, the valve opening and closing control unit 73 controls the valve device 626 to close (step S101). Then, the valve opening and closing control unit 73 proceeds to a step S102.

In the step S102, the valve opening and closing control unit 73 determines whether the temperature of the first temperature control medium TCM1 detected by the first temperature control medium temperature detection unit 71 is lower than a predetermined temperature Tset1 [° C.]. The predetermined temperature Tset1 is, for example, 80 [° C.].

If the temperature of the first temperature control medium TCM1 detected by the first temperature control medium temperature detection unit 71 is lower than the predetermined temperature Tset1 [° C.] in the step S102 (step S102: YES), the valve opening and closing control unit 73 proceeds to a step S202.

If the temperature of the first temperature control medium TCM1 detected by the first temperature control medium temperature detection unit 71 in the step S102 is not lower than the predetermined temperature Tset1 [° C.], that is, if the temperature of the first temperature control medium TCM1 detected by the first temperature control medium temperature detection unit 71 is equal to or higher than the predetermined temperature Tset1 [° C.] (step S102: NO), the valve opening and closing control unit 73 proceeds to a step S103.

In the step S103, the valve opening and closing control unit 73 determines whether the uphill travel determination unit 76 determines that the vehicle V is in uphill travel.

The uphill travel determination unit 76 stores, for example, a table in which a threshold gradient angle is set corresponding to each vehicle speed of the vehicle V. As an example, the threshold gradient angle is 10° when the vehicle speed of the vehicle V is 10 [km/h], the threshold gradient angle is 6° when the vehicle speed of the vehicle V is 80 [km/h], and the threshold gradient angle is 4° when the vehicle speed of the vehicle V is 120 [km/h].

The uphill travel determination unit 76 determines whether the vehicle V is in uphill travel based on the vehicle speed of the vehicle V detected by the vehicle speed detection unit 74 and the gradient angle of the road surface on which the vehicle V travels and detected by the gradient angle detection unit 75. As an example, by referring to the above table in which the threshold gradient angle is set corresponding to each vehicle speed of the vehicle V, if the gradient angle of the road surface on which the vehicle V travels and detected by the gradient angle detection unit 75 is equal to or greater than the threshold gradient angle corresponding to the vehicle speed of the vehicle V detected by the vehicle speed detection unit 74, it is determined that the vehicle V is in uphill travel, and if the gradient angle is less than the threshold gradient angle corresponding to the vehicle speed of the vehicle V detected by the vehicle speed detection unit 74, it is determined that the vehicle V is not in uphill travel.

If the uphill travel determination unit 76 determines in the step S103 that the vehicle V is in uphill travel (step S103: YES), the valve opening and closing control unit 73 proceeds to a step S201, controls the valve device 626 to open, and then proceeds to the step S202.

If the uphill travel determination unit 76 determines in the step S103 that the vehicle V is not in uphill travel (step S103: NO), the valve opening and closing control unit 73 proceeds to a step S104.

In the step S104, the valve opening and closing control unit 73 determines whether the slip determination unit 77 determines that at least one wheel of the vehicle V is spinning.

For example, the vehicle V includes front, rear, left and right wheels, each of which is provided with a wheel speed sensor that detects a rotation speed of the wheel, and based on a detection signal output from the wheel speed sensor provided on each wheel, the slip determination unit 77 determines that either the left or right front wheel is spinning if a wheel speed difference between the left and right front wheels is equal to or greater than a predetermined value, and determines that either the left or right rear wheel is spinning if a wheel speed difference between the left and right rear wheels is equal to or greater than a predetermined value.

If the slip determination unit 77 determines in the step S104 that at least one wheel of the vehicle V is spinning (step S104: YES), the valve opening and closing control unit 73 proceeds to the step S201, controls the valve device 626 to open, and then proceeds to the step S202.

If the slip determination unit 77 determines in the step S104 that the wheels of the vehicle V are not spinning (step S104: NO), the valve opening and closing control unit 73 proceeds to a step S105.

In the step S105, the valve opening and closing control unit 73 determines whether the driving torque of the vehicle V detected by the driving torque detection unit 78 is equal to or greater than a predetermined value Nset1 [N·m]. The predetermined value Nset1 [N·m] is, for example, a value greater than a maximum torque required when the vehicle V travels on its own without towing a towed vehicle such as a trailer or other vehicles such as a broken-down vehicle, and is a value of a driving torque required when traveling while towing a towed vehicle or other vehicles. The predetermined value Nset1 [N·m] is, for example, 4000 [N·m].

For example, the vehicle V is provided with a torque sensor that detects a torsion angle of a driving shaft of the vehicle V, and the driving torque detection unit 78 detects the driving torque of the vehicle V based on a detection signal corresponding to the torsion angle of the driving shaft output from this torque sensor.

If the driving torque of the vehicle V detected in the step S105 by the driving torque detection unit 78 is equal to or greater than the predetermined value Nset1 [N·m] (step S105: YES), the valve opening and closing control unit 73 proceeds to the step S201, controls the valve device 626 to open, and then proceeds to the step S202.

In the step S105, if the driving torque of the vehicle V detected by the driving torque detection unit 78 is not equal to or greater than the predetermined value Nset1 [N·m], that is, if the driving torque of the vehicle V detected by the driving torque detection unit 78 is less than the predetermined value Nset1 [N·m] (step S105: NO), the valve opening and closing control unit 73 proceeds to the step S202 while maintaining the control to close the valve device 626.

In the step S202, the valve opening and closing control unit 73 determines whether the vehicle V switches from the power-on state to the power-off state.

If the vehicle V switches from the power-on state to the power-off state in the step S202 (step S202: YES), the valve opening and closing control unit 73 ends the series of control.

If the vehicle V remains in the power-on state and does not switch to the power-off state (step S202: NO) in the step S202, the valve opening and closing control unit 73 returns to the step S102.

In this way, the valve opening and closing control unit 73 controls the valve device 626 to close regardless of the temperature of the second temperature control medium TCM2 when the temperature of the first temperature control medium TCM1 detected by the first temperature control medium temperature detection unit 71 is below the predetermined temperature Tset1 [° C.], and controls the valve device 626 to open when the temperature of the first temperature control medium TCM1 detected by the first temperature control medium temperature detection unit 71 becomes equal to or higher than the predetermined temperature Tset1 [° C.] while the valve device 626 is closed.

In general, the higher the temperature of the first temperature control medium TCM1, the lower the viscosity thereof. Therefore, in the first temperature control circuit 61, when the first temperature control medium TCM1 lubricates and controls the temperatures of the electric motor 20, the electric generator 30, and the transmission device 40, the higher the temperature of the first temperature control medium TCM1, the more a friction loss decreases.

In the present embodiment, when the temperature of the first temperature control medium TCM1 is lower than the predetermined temperature Tset1 [° C.], the electric motor 20 and the electric generator 30 are not at a high temperature and do not require cooling. On the other hand, since the valve device 626 is closed, the second temperature control medium TCM2 cooled by the radiator 622 is not supplied to the heat exchanger 63. Therefore, the first temperature control medium TCM1 is not cooled by the heat exchanger 63, and the temperature of the first temperature control medium TCM1 rises due to the heat generated by the electric motor 20 and the electric generator 30, causing the viscosity of the first temperature control medium TCM1 to decrease, thereby reducing the friction loss and improving fuel efficiency of the vehicle V. When the temperature of the first temperature control medium TCM1 is equal to or higher than the predetermined temperature Tset1 [° C.], the valve device 626 opens and the second temperature control medium TCM2 cooled by the radiator 622 is supplied to the heat exchanger 63, where the first temperature control medium TCM1 is cooled by heat exchange with the second temperature control medium TCM2, and the first temperature control medium TCM1 cools the electric motor 20 and the electric generator 30.

As a result, when cooling of the electric motor 20 and the electric generator 30 is not necessary, the viscosity of the first temperature control medium TCM1 can be reduced by closing the valve device 626, thereby reducing the friction loss and improving the fuel efficiency of the vehicle V. On the other hand, when cooling of the electric motor 20 and the electric generator 30 is necessary, the valve device 626 can be opened to cool the first temperature control medium TCM1, thereby cooling the electric motor 20 and the electric generator 30.

In this way, when cooling of the electric motor 20 and the electric generator 30 is necessary, the electric motor 20 and the electric generator 30 are cooled by the first temperature control medium TCM1, and when cooling of the electric motor 20 and the electric generator 30 is not necessary, the temperature of the first temperature control medium TCM1 is raised, thereby improving the fuel efficiency of the vehicle V.

Furthermore, even when the temperature of the first temperature control medium TCM1 detected by the first temperature control medium temperature detection unit 71 is lower than the predetermined temperature Tset1 [° C.], if the uphill travel determination unit 76 determines that the vehicle V is in uphill travel, the valve opening and closing control unit 73 controls the valve device 626 to open, and therefore, when the vehicle V travels in a manner that makes the electric motor 20 and the electric generator 30 more likely to generate heat than during normal travel, the electric motor 20 and the electric generator 30 can be rapidly cooled.

Even when the temperature of the first temperature control medium TCM1 detected by the first temperature control medium temperature detection unit 71 is lower than the predetermined temperature Tset1 [° C.], if the slip determination unit 77 determines that at least one wheel of the vehicle V is spinning, the valve opening and closing control unit 73 controls the valve device 626 to open, and therefore, when the vehicle V travels in a manner that makes the electric motor 20 and the electric generator 30 more likely to generate heat than during normal travel, the electric motor 20 and the electric generator 30 can be rapidly cooled.

Even when the temperature of the first temperature control medium TCM1 detected by the first temperature control medium temperature detection unit 71 is lower than the predetermined temperature Tset1 [° C.], if the driving torque detected by the driving torque detection unit 78 is equal to or greater than the predetermined value Nset1 [N·m], the valve opening and closing control unit 73 controls the valve device 626 to open, and therefore, the electric motor 20 and the electric generator 30 can be rapidly cooled when the vehicle V performs towing or other traveling that makes the electric motor 20 and the electric generator 30 more likely to generate heat than during normal travel.

In the present embodiment, in the control flow for the valve device 626 in the valve opening and closing control unit 73, when the temperature of the first temperature control medium TCM1 detected by the first temperature control medium temperature detection unit 71 is lower than the predetermined temperature Tset1 [° C.], whether the uphill travel determination unit 76 determines that the vehicle V is in uphill travel, whether the slip determination unit 77 determines that at least one wheel of the vehicle V is spinning, and whether the driving torque detection unit 78 determines that the detected driving torque is equal to or greater than the predetermined value Nset1 [N·m] will be determined in this order.

As a result, since whether the traveling state of the vehicle V is a traveling state in which the electric motor 20 and the electric generator 30 are more likely to generate heat in order, when the traveling state of the vehicle V is a traveling state in which the electric motor 20 and the electric generator 30 are more likely to generate heat, the electric motor 20 and the electric generator 30 can be cooled more quickly.

Although an embodiment of the present disclosure has been described above with reference to the accompanying drawings, it is needless to say that the present disclosure is not limited to the embodiment. It is apparent that those skilled in the art can conceive of various modifications and alterations within the scope described in the claims, and it is understood that such modifications and alterations naturally fall within the technical scope of the present disclosure. In addition, the respective constituent elements in the above embodiment may be combined as desired without departing from the gist of the disclosure.

For example, in the present embodiment, the vehicle V is equipped with the internal combustion engine ICE, but the vehicle V may be an electric vehicle that does not include the internal combustion engine ICE. In the present embodiment, the vehicle V is equipped with the electric generator 30, but the vehicle V may be a vehicle that does not include the electric generator 30.

In the present specification, at least the following matters are described. In the parentheses, the corresponding constituent elements and the like in the above embodiment are shown as examples, but the present disclosure is not limited thereto.
(1) A vehicle temperature control system (vehicle temperature control system 10) equipped in a vehicle (vehicle V) including a rotary electric machine (electric motor 20), a transmission device (transmission device 40), and a power conversion device (power conversion device 50) configured to control electric power supplied to the rotary electric machine, the vehicle temperature control system including:
a first temperature control circuit (first temperature control circuit 61) in which a first pump (first pump 611) is provided and a first temperature control medium (first temperature control medium TCM1) circulates to control temperatures of the rotary electric machine and the transmission device;
a second temperature control circuit (second temperature control circuit 62) in which a second pump (second pump 621) is provided and a second temperature control medium (second temperature control medium TCM2) circulates to control a temperature of the power conversion device;
a heat exchanger (heat exchanger 63) that exchanges heat between the first temperature control medium and the second temperature control medium;
a flow regulating valve (valve device 626) configured to regulate a flow rate of the second temperature control medium flowing through the heat exchanger; and
a control device (control device ECU) configured to control the flow regulating valve, in which
the second temperature control circuit includes
   a pumping flow path (pumping flow path 620a) provided with the second pump and having one end provided with a branch portion (branch portion 624) and the other end provided with a merging portion (merging portion 625),
   a first branching flow path (first branching flow path 620b1) provided with the power conversion device and having one end connected to the branch portion and the other end connected to the merging portion, and
   a second branching flow path (second branching flow path 620b2) provided with the heat exchanger and the flow regulating valve, having one end connected to the branch portion and the other end connected to the merging portion, and formed in parallel with the first branching flow path,
the pumping flow path is provided with a radiator (radiator 622) configured to exchange heat between the second temperature control medium and outside air,
the control device includes
   a first temperature control medium temperature detector (first temperature control medium temperature detection unit 71) configured to detect a temperature of the first temperature control medium, and
   a valve opening and closing controller (valve opening and closing control unit 73) configured to control opening and closing of the flow regulating valve, and
the valve opening and closing controller is configured to
   control the flow regulating valve to close when the temperature of the first temperature control medium detected by the first temperature control medium temperature detector is lower than a predetermined temperature (predetermined temperature Tset1), and
   control the flow regulating valve to open when the temperature of the first temperature control medium detected by the first temperature control medium temperature detector is equal to or higher than the predetermined temperature while the flow regulating valve is closed.

According to (1), when cooling of the rotary electric machine is necessary, the rotary electric machine is cooled by the first temperature control medium, and when cooling of the rotary electric machine is unnecessary, the temperature of the first temperature control medium is increased, thereby improving the fuel efficiency of the vehicle.
(2) The vehicle temperature control system according to (1), in which
the control device further includes
   a vehicle speed detector (vehicle speed detection unit 74) configured to detect a vehicle speed of the vehicle;
   a gradient angle detector (gradient angle detection unit 75) configured to detect a gradient angle of a road surface on which the vehicle travels, and
   an uphill travel determination unit (uphill travel determination unit 76) configured to determine whether the vehicle is in uphill travel based on detection values of the vehicle speed detector and the gradient angle detector, and
the valve opening and closing controller is configured to cause the flow regulating valve to open when the uphill travel determination unit determines that the vehicle is in uphill travel, even when the temperature of the first temperature control medium detected by the first temperature control medium temperature detector is lower than the predetermined temperature.

According to (2), even when the temperature of the first temperature control medium detected by the first temperature control medium temperature detector is lower than the predetermined temperature, if the vehicle travels in a manner that makes the rotary electric machine more likely to generate heat than during normal travel, the rotary electric machine can be rapidly cooled.
(3) The vehicle temperature control system according to (1), in which
the control device further includes a slip determination unit (slip determination unit 77) configured to determine whether at least one wheel of the vehicle is spinning, and
the valve opening and closing controller is configured to cause the flow regulating valve to open when the slip determination unit determines that at least one wheel of the vehicle is spinning, even when the temperature of the first temperature control medium detected by the first temperature control medium temperature detector is lower than the predetermined temperature.

According to (3), even when the temperature of the first temperature control medium detected by the first temperature control medium temperature detector is lower than the predetermined temperature, if the vehicle travels in a manner that makes the rotary electric machine more likely to generate heat than during normal travel, the rotary electric machine can be rapidly cooled.
(4) The vehicle temperature control system according to (1), in which
the control device further includes a driving torque detector (driving torque detection unit 78) configured to detect a driving torque of the vehicle, and
the valve opening and closing controller is configured to cause the flow regulating valve to open when the driving torque detected by the driving torque detector is equal to or greater than a predetermined value, even when the temperature of the first temperature control medium detected by the first temperature control medium temperature detector is lower than the predetermined temperature.

According to (4), even when the temperature of the first temperature control medium detected by the first temperature control medium temperature detector is lower than the predetermined temperature, if the vehicle is in towing travel or the like, which makes the rotary electric machine more likely to generate heat than during normal travel, the rotary electric machine can be rapidly cooled.
(5) A vehicle (vehicle V), including:
a rotary electric machine (electric motor 20);
a transmission device (transmission device 40);
a power conversion device (power conversion device 50) configured to control electric power supplied to the rotary electric machine; and
a vehicle temperature control system (vehicle temperature control system 10), in which
the vehicle temperature control system includes
   a first temperature control circuit (first temperature control circuit 61) in which a first pump (first pump 611) is provided and a first temperature control medium (first temperature control medium TCM1) circulates to control temperatures of the rotary electric machine and the transmission device,
   a second temperature control circuit (second temperature control circuit 62) in which a second pump (second pump 621) is provided and a second temperature control medium (second temperature control medium TCM2) circulates to control a temperature of the power conversion device,
   a heat exchanger (heat exchanger 63) that exchanges heat between the first temperature control medium and the second temperature control medium,
   a flow regulating valve (valve device 626) configured to regulate a flow rate of the second temperature control medium flowing through the heat exchanger, and
   a control device (control device ECU) configured to control the flow regulating valve,
the second temperature control circuit includes
   a pumping flow path (pumping flow path 620a) provided with the second pump and having one end provided with a branch portion (branch portion 624) and the other end provided with a merging portion (merging portion 625),
   a first branching flow path (first branching flow path 620b1) provided with the power conversion device and having one end connected to the branch portion and the other end connected to the merging portion, and
   a second branching flow path (second branching flow path 620b2) provided with the heat exchanger and the flow regulating valve, having one end connected to the branch portion and the other end connected to the merging portion, and formed in parallel with the first branching flow path,
the pumping flow path is provided with a radiator (radiator 622) configured to exchange heat between the second temperature control medium and outside air,
the control device includes
   a first temperature control medium temperature detector (first temperature control medium temperature detection unit 71) configured to detect a temperature of the first temperature control medium, and
   a valve opening and closing controller (valve opening and closing control unit 73) configured to control opening and closing of the flow regulating valve, and
the valve opening and closing controller is configured to
   control the flow regulating valve to close when the temperature of the first temperature control medium detected by the first temperature control medium temperature detector is lower than a predetermined temperature (predetermined temperature Tset1), and
   control the flow regulating valve to open when the temperature of the first temperature control medium detected by the first temperature control medium temperature detector is equal to or higher than the predetermined temperature while the flow regulating valve is closed.

According to (5), when cooling of the rotary electric machine is necessary, the rotary electric machine is cooled by the first temperature control medium, and when cooling of the rotary electric machine is unnecessary, the temperature of the first temperature control medium is increased, thereby improving the fuel efficiency of the vehicle.

1. A vehicle temperature control system equipped in a vehicle including a rotary electric machine, a transmission device, and a power conversion device configured to control electric power supplied to the rotary electric machine, the vehicle temperature control system comprising:
a first temperature control circuit in which a first pump is provided and a first temperature control medium circulates to control temperatures of the rotary electric machine and the transmission device;
a second temperature control circuit in which a second pump is provided and a second temperature control medium circulates to control a temperature of the power conversion device;
a heat exchanger that exchanges heat between the first temperature control medium and the second temperature control medium;
a flow regulating valve configured to regulate a flow rate of the second temperature control medium flowing through the heat exchanger; and
a control device configured to control the flow regulating valve, wherein
the second temperature control circuit includes
a pumping flow path provided with the second pump and having one end provided with a branch portion and the other end provided with a merging portion,
a first branching flow path provided with the power conversion device and having one end connected to the branch portion and the other end connected to the merging portion, and
a second branching flow path provided with the heat exchanger and the flow regulating valve, having one end connected to the branch portion and the other end connected to the merging portion, and formed in parallel with the first branching flow path,
the pumping flow path is provided with a radiator configured to exchange heat between the second temperature control medium and outside air,
the control device includes
a first temperature control medium temperature detector configured to detect a temperature of the first temperature control medium, and
a valve opening and closing controller configured to control opening and closing of the flow regulating valve, and
the valve opening and closing controller is configured to
cause the flow regulating valve to close, when the temperature of the first temperature control medium detected by the first temperature control medium temperature detector is lower than a predetermined temperature, and
cause the flow regulating valve to open, when the temperature of the first temperature control medium detected by the first temperature control medium temperature detector becomes equal to or higher than the predetermined temperature while the flow regulating valve is closed.

2. The vehicle temperature control system according to claim 1, wherein
the control device further includes
a vehicle speed detector configured to detect a vehicle speed of the vehicle;
a gradient angle detector configured to detect a gradient angle of a road surface on which the vehicle travels, and
an uphill travel determination unit configured to determine whether the vehicle is in uphill travel based on detection values of the vehicle speed detector and the gradient angle detector, and
the valve opening and closing controller is configured to cause the flow regulating valve to open when the uphill travel determination unit determines that the vehicle is in uphill travel, even when the temperature of the first temperature control medium detected by the first temperature control medium temperature detector is lower than the predetermined temperature.

3. The vehicle temperature control system according to claim 1, wherein
the control device further includes a slip determination unit configured to determine whether at least one wheel of the vehicle is spinning, and
the valve opening and closing controller is configured to cause the flow regulating valve to open when the slip determination unit determines that at least one wheel of the vehicle is spinning, even when the temperature of the first temperature control medium detected by the first temperature control medium temperature detector is lower than the predetermined temperature.

4. The vehicle temperature control system according to claim 1, wherein
the control device further includes a driving torque detector configured to detect a driving torque of the vehicle, and
the valve opening and closing controller is configured to cause the flow regulating valve to open when the driving torque detected by the driving torque detector is equal to or greater than a predetermined value, even when the temperature of the first temperature control medium detected by the first temperature control medium temperature detector is lower than the predetermined temperature.

5. A vehicle, comprising:
a rotary electric machine;
a transmission device;
a power conversion device configured to control electric power supplied to the rotary electric machine; and
a vehicle temperature control system, wherein
the vehicle temperature control system includes
a first temperature control circuit in which a first pump is provided and a first temperature control medium circulates to control temperatures of the rotary electric machine and the transmission device,
a second temperature control circuit in which a second pump is provided and a second temperature control medium circulates to control a temperature of the power conversion device,
a heat exchanger that exchanges heat between the first temperature control medium and the second temperature control medium,
a flow regulating valve configured to regulate a flow rate of the second temperature control medium flowing through the heat exchanger, and
a control device configured to control the flow regulating valve, the second temperature control circuit includes
a pumping flow path provided with the second pump and having one end provided with a branch portion and the other end provided with a merging portion,
a first branching flow path provided with the power conversion device and having one end connected to the branch portion and the other end connected to the merging portion, and
a second branching flow path provided with the heat exchanger and the flow regulating valve, having one end connected to the branch portion and the other end connected to the merging portion, and formed in parallel with the first branching flow path,
the pumping flow path is provided with a radiator configured to exchange heat between the second temperature control medium and outside air,
the control device includes
a first temperature control medium temperature detector configured to detect a temperature of the first temperature control medium, and
a valve opening and closing controller configured to control opening and closing of the flow regulating valve, and
the valve opening and closing controller is configured to
cause the flow regulating valve to close, when the temperature of the first temperature control medium detected by the first temperature control medium temperature detector is lower than a predetermined temperature, and
cause the flow regulating valve to open, when the temperature of the first temperature control medium detected by the first temperature control medium temperature detector becomes equal to or higher than the predetermined temperature while the flow regulating valve is closed.
